(19) United States
(12) Patent Application Publication
(10) Pub. No.: US 2025/0098274 A1
(43) Pub. Date: Mar. 20, 2025

(54) III-NITRIDE TRANSISTOR WITH TOP AND BOTTOM CAP LAYERS WITH ETCH STOP

(71) Applicant: Finwave Semiconductor, Inc., Belmont, MA (US)

(72) Inventors: Dongfei Pei, Waban, MA (US); Bin Lu, Fremont, CA (US)

(21) Appl. No.: 18/824,415

(22) Filed: Sep. 4, 2024

Related U.S. Application Data
(60) Provisional application No. 63/539,199, filed on Sep. 19, 2023.

(51) Int. Cl. H01L 29/51; H01L 21/02; H01L 21/768; H01L 29/20; H01L 29/45

(52) U.S. Cl. CPC H10D 64/683; H01L 21/02362; H01L 21/02458; H01L 21/76832; H10D 62/85; H10D 62/8503; H10D 64/62

(57) ABSTRACT

A new transistor structure for use with III-Nitride semiconductor structures is disclosed. This transistor adds a top cap layer, etch stop layer and bottom cap layer between the gate electrode and the barrier layer. This structure enables a fabrication process in which the barrier layer is not subjected to plasma etching, which is a cause of etch related variations. In some embodiments, the bottom cap layer and optionally the etch stop layer extend from the source electrode to the drain electrode. A gate dielectric layer may optionally be included between the gate electrode and the top cap layer.

This application claim priority to U.S. Provisional Patent Application Ser. No. 63/539,199, filed Sep. 19, 2023, the disclosure of which is incorporated herein by reference in its entirety.

### FIELD

Embodiments of the present disclosure relate to a transistor and methods for making a transistor with top and bottom cap layers with an etch stop.

### BACKGROUND

FIG. 1 shows a typical conventional III-Nitride semiconductor transistor with p-type gate which comprises a substrate 1, a buffer layer 2 on top of the substrate, a GaN channel layer 3 on top of the buffer layer and AlGaN barrier layer 4 on top of the channel layer. The substrate 1 is SiC, sapphire, Si or free-standing GaN semiconductors. A nucleation layer exists between the buffer layer 2 and the substrate 1. The AlGaN barrier layer 4 has a wider band-gap than the GaN channel 3. A P-GaN (p-type GaN) layer 5 on the AlGaN barrier layer 3 is used underneath the gate electrode 6 to realize a normally-off transistor. Source electrode 7 and drain electrode 8 are disposed on opposite sides of the gate electrode 6.

In the fabrication of this structure, the P-GaN layer 5 is etched away from the surfaces outside of the gate region using plasma based etching techniques. As a result, the surface of the AlGaN barrier layer 4 will be exposed, resulting in plasma etching damage. Also, due to the non-uniform thickness of the P-GaN layer and the plasma center-edge etch rate variation, the surface of the AlGaN barrier layer 4 may experience different etching length and varying amount of plasma etch damage. As a result, the finished transistors suffer from variations and etching related degradations.

Thus, it may be beneficial to create a fabrication process that does not suffer from these drawbacks.

### SUMMARY

A new transistor structure for use with III-Nitride semiconductor structures is disclosed. This transistor adds a top cap layer, etch stop layer and bottom cap layer between the gate electrode and the barrier layer. This structure enables a fabrication process in which the barrier layer is not subjected to plasma etching, which is a cause of etch related variations. In some embodiments, the bottom cap layer and optionally the etch stop layer extend from the source electrode to the drain electrode. A gate dielectric layer may optionally be included between the gate electrode and the top cap layer.

According to one embodiment, a semiconductor structure for use in a III-Nitride (III-N) semiconductor device is disclosed. The semiconductor structure comprises a channel layer; a barrier layer, wherein electrons are formed at an interface between the channel layer and the barrier layer; a source electrode and a drain electrode disposed in ohmic contact regions to form an electrical connection to electrons at the interface between the channel layer and the barrier layer; a gate electrode disposed between the source electrode and the drain electrode in a gate region; a bottom cap layer disposed on the barrier layer; an etch stop layer disposed on the bottom cap layer; and a top cap layer disposed beneath the gate electrode and on the etch stop layer. In some embodiments, the bottom cap layer extends from the drain electrode to the source electrode. In some embodiments, the top cap layer is disposed only in the gate region. In some embodiments, the top cap layer comprises Mg-doped p-type GaN or InGaN or a III-Nitride semiconductor that has a lower Al composition than the etch stop layer. In some embodiments, the etch stop layer is disposed only in the gate region. In some embodiments, the etch stop layer extends from the drain electrode to the source electrode. In some embodiments, the etch stop layer comprises a higher aluminum composition than the bottom cap layer. In certain embodiments, the etch stop layer comprises AlN. In some embodiments, the bottom cap layer comprises a lower aluminum composition than the barrier layer. In certain embodiments, the bottom cap layer comprises GaN. In some embodiments, a gate dielectric layer is disposed between the gate electrode and the top cap layer.

According to another embodiment, a method of fabricating a III-Nitride (III-N) semiconductor device is disclosed. The method comprises depositing on a substrate, a buffer layer, a channel layer, a barrier layer, a bottom cap layer, an etch stop layer and a top cap layer, wherein the etch stop layer has a higher aluminum composition than the bottom cap layer and the top cap layer; using a mask to remove a portion of the top cap layer, using an etch process that is highly selective to the top cap layer over the etch stop layer; removing the mask; depositing a dielectric layer over an entirety of the substrate; depositing a source electrode and a drain electrode in ohmic contact regions to form an electrical connection to electrons at an interface between the channel layer and the barrier layer; removing a portion of the dielectric layer in a gate region; and depositing a gate electrode on top of the top cap layer in the gate region. In some embodiments, the method also comprises etching a portion of the etch stop layer after etching the top cap layer and before removing the mask. In certain embodiments, etching the etch stop layer is performed using tetramethylammonium hydroxide (TMAH), a standard clean 1 (SC1), which includes a solution of ammonium hydroxide (NH₃OH), hydrogen peroxide (H₂O₂) and water, or an oxygen plasma in conjunction with a wet HCl etch. In some embodiments, etching of the top cap layer is performed using a plasma containing fluorine or oxygen in combination with chlorine, or a plasma containing boron trichloride and/or sulfur hexafluorine. In some embodiments, the etch stop layer comprises AlN. In some embodiments, the bottom cap layer comprises GaN. In some embodiments, the top cap layer comprises Mg-doped p-type GaN or InGaN or a III-Nitride semiconductor that has a lower Al composition than the etch stop layer.

### BRIEF DESCRIPTION OF THE FIGURES

For a better understanding of the present disclosure, reference is made to the accompanying drawings, which are incorporated herein by reference and in which:

FIG. 1 shows the layout of a conventional III-Nitride transistor according to the prior art;

FIGS. 2A-2H show a fabrication sequence that may be used to create the III-Nitride transistor;

FIG. 3 shows a variation of the III-Nitride transistor of FIG. 2H;

FIG. 4 shows a variation of the III-Nitride transistor of FIG. 3;

FIG. 5 shows a variation of the III-Nitride transistor of FIG. 4; and

FIG. 6 is a flowchart showing the sequence used to fabricate the III-Nitride transistor of FIG. 2H.

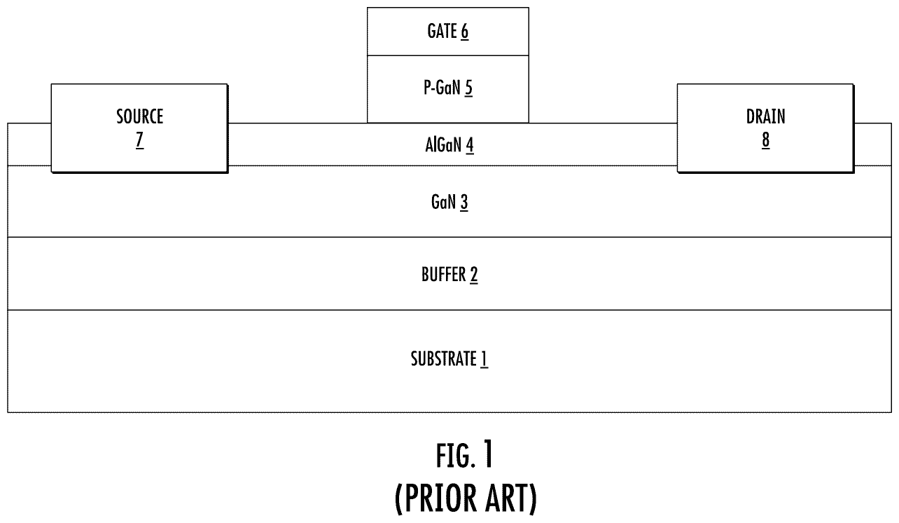

### DETAILED DESCRIPTION

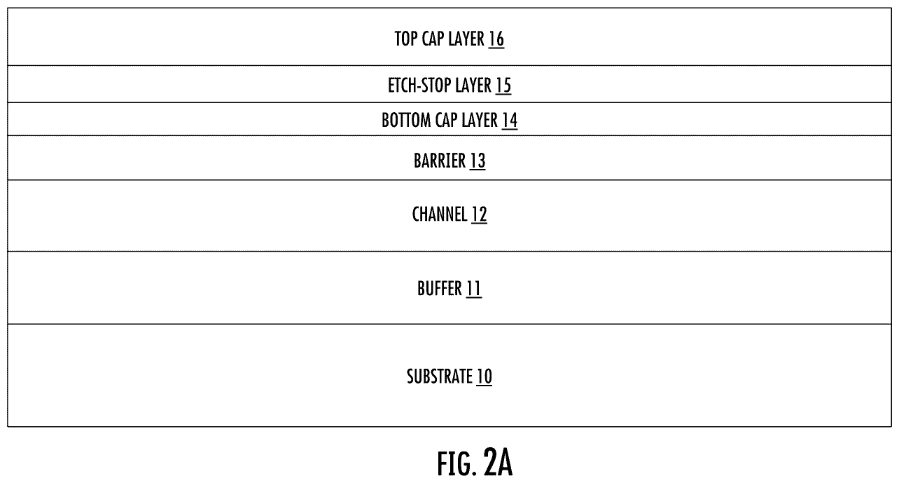

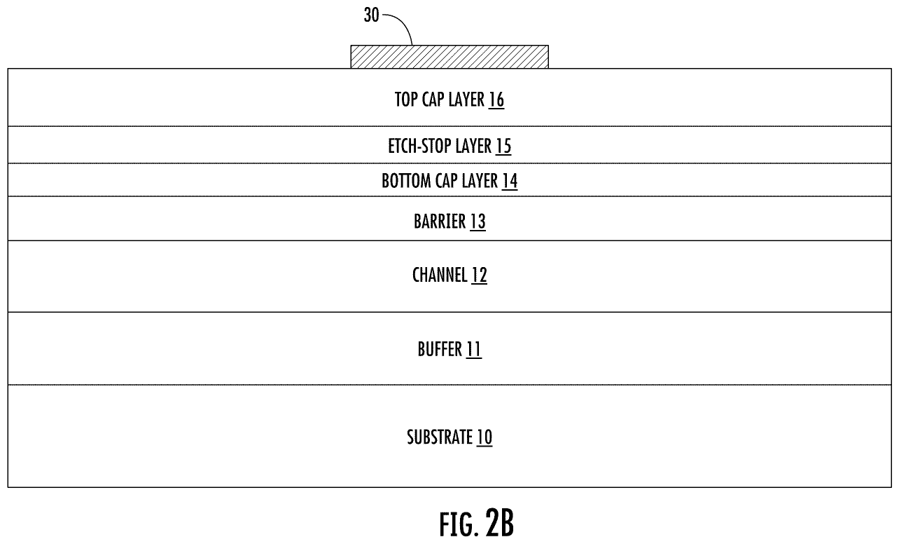

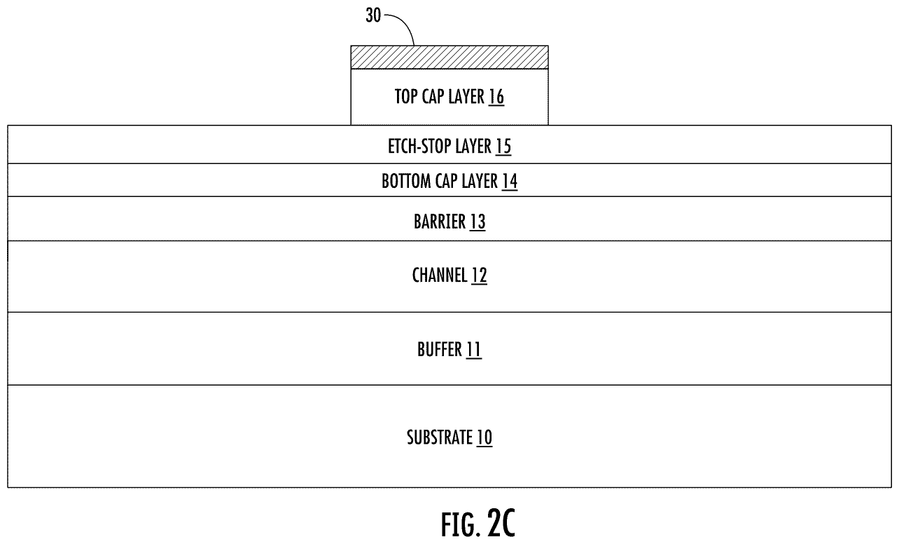

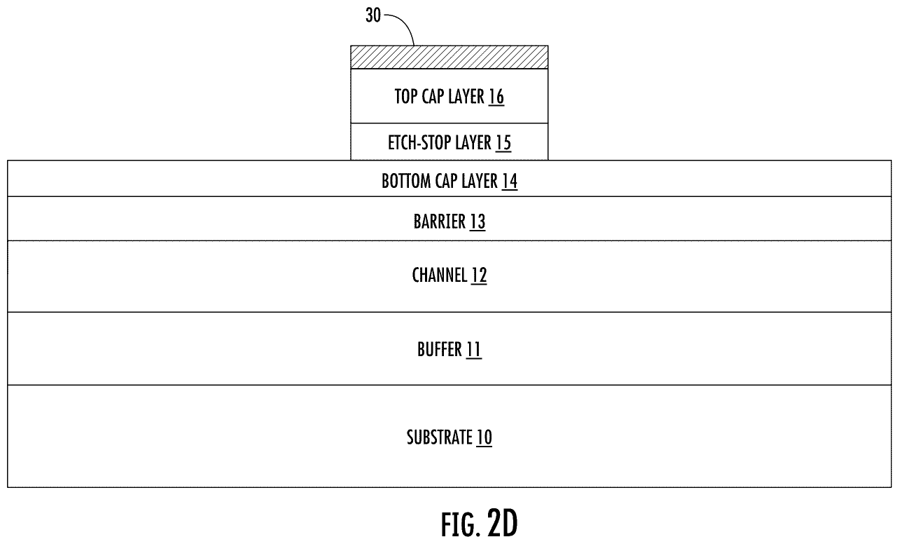

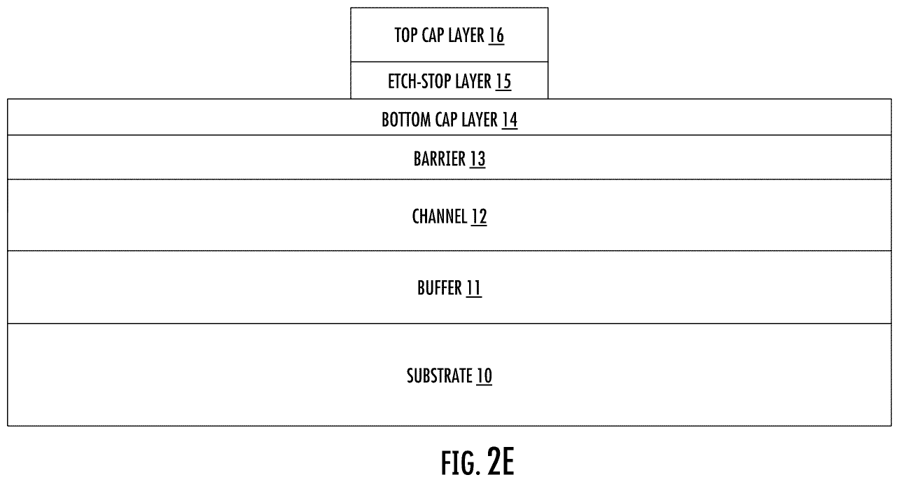

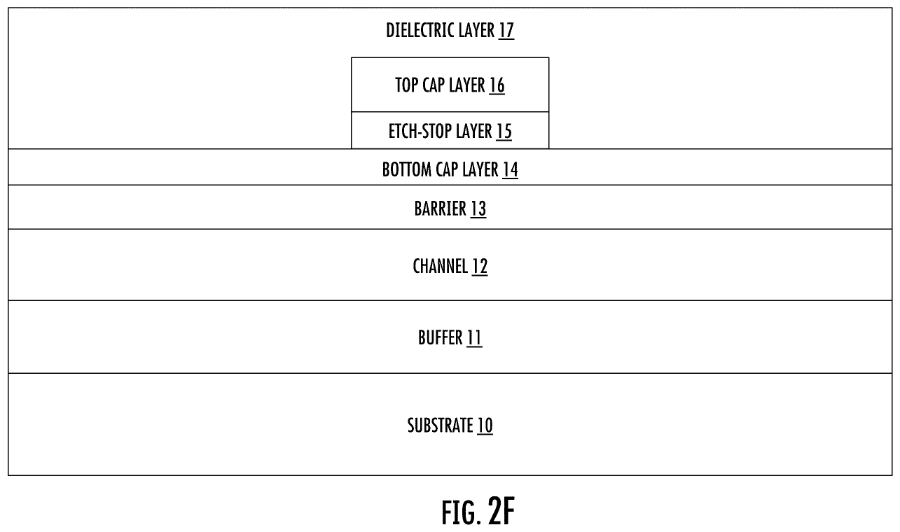

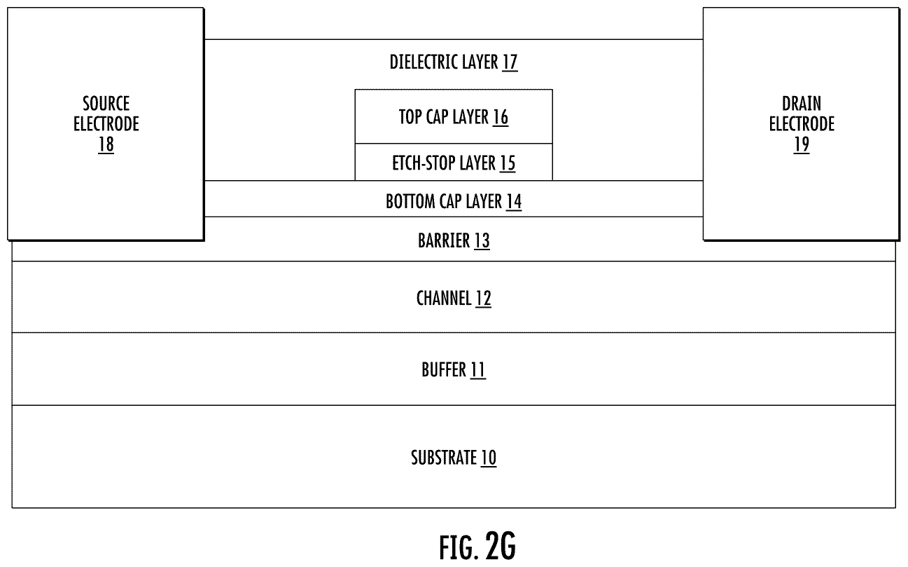

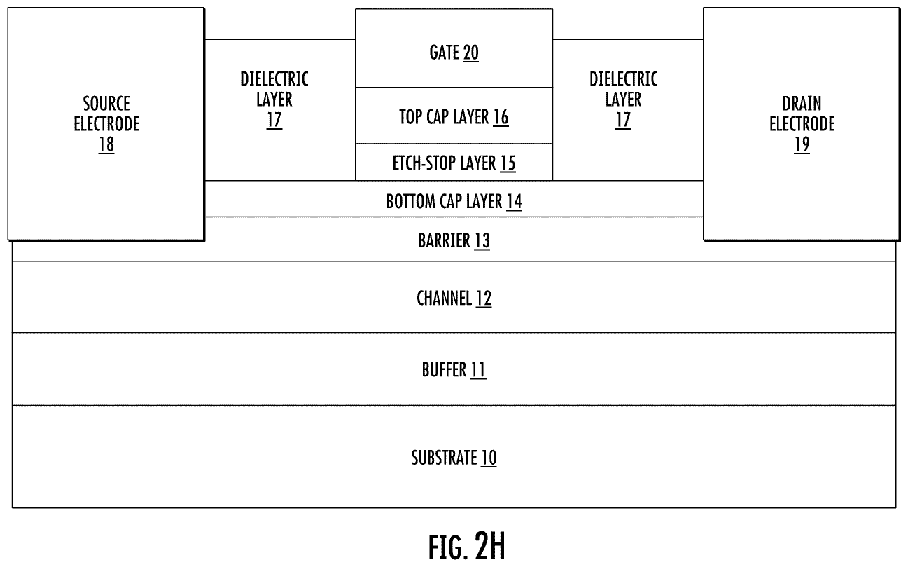

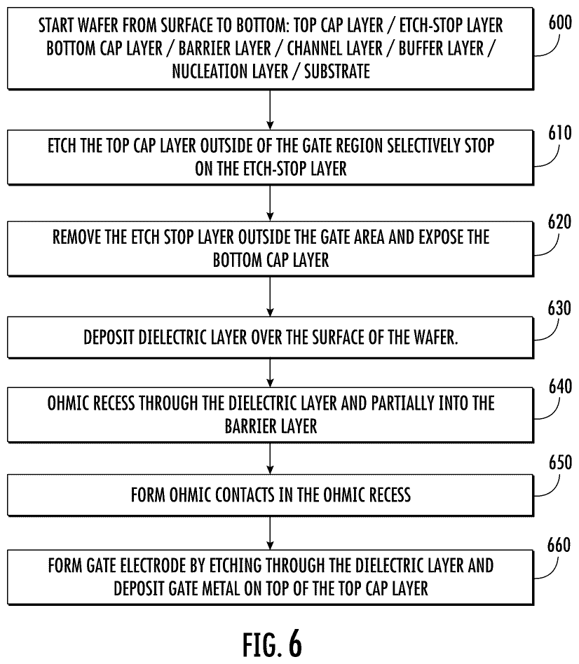

This disclosure describes III-Nitride transistor device with less etch related defects and variations. FIG. 6 shows a flowchart to fabricate the III-Nitride transistor according to one embodiment. FIGS. 2A-2H show cross-sectional views of the transistor during its fabrication process.

First, as shown in Box 600 and FIG. 2A, the basic III-Nitride transistor structure is formed using multiple deposition steps. The resulting structure includes a substrate 10, a buffer layer 11, a channel layer 12, a barrier layer 13, a bottom cap layer 14, an etch stop layer 15 and a top cap layer 16. In many embodiments, a nucleation layer may be disposed between the substrate 10 and the buffer layer 11.

The substrate 10 may be SiC, sapphire, Si, free-standing GaN or any other substrate including multiple layers including polycrystalline AlN. A nucleation layer may be disposed between the buffer layer 11 and surface of the substrate 10. The nucleation layer may include AlN.

A buffer layer 11 is formed over the nucleation layer. The buffer layer 11 may have a thickness between 0.5 nm and several microns, although other thicknesses are within the scope of the disclosure. The buffer layer 11 may comprise III-nitride semiconductors including GaN, AlGaN, InGaN, InAlN, InAlGaN and AlN.

A channel layer 12 is formed over the buffer layer 11. The channel layer 12 comprises a semiconductor material selected from InGaN, GaN, or any other suitable semiconductor material or combination of materials.

Carriers, which may be free electrons, exist in the channel layer 12 to conduct electrical current between the drain contact and the source contact.

The channel layer 12 may comprise a single layer such as a GaN layer, or multiple layers. In one example, the channel layer 12 comprises a back-barrier structure, such as a GaN layer over an AlGaN layer (GaN/AlGaN) or a GaN layer over an InGaN layer and another GaN layer (GaN/InGaN/GaN). In another example, the channel layer 12 has a superlattice structure formed by repeating a bi-layer structure of AlGaN/GaN or AlN/GaN. The thickness of the channel layer 12 may be 5 nm, although other thicknesses may be used.

A barrier layer 13 is formed over the channel layer 12. The barrier layer 13 may be made of III-nitride semiconductors selected from AlGaN, InAlN, AlN or InAlGaN. The barrier layer 13 may be un-doped, or doped with Si or other impurities. The barrier layer 13 has a wider band-gap than the channel layer 12. The barrier layer 13 may be between 0.2 nm and 30 nm.

The bottom cap layer 14 comprises III-nitride semiconductors, such as doped or un-doped GaN material or an AlGaN material with lower Al composition than the barrier layer 13. The thickness of the bottom cap layer 14 may be less than 10 nm, such as between 0.5-5 nm.

The etch stop layer 15 comprises a III-Nitride semiconductor with a higher aluminum composition than the bottom cap layer 14. In one particular embodiment, the etch stop layer 15 may be AlN. The thickness of the etch stop layer 15 may be very thin, such as less than 2 nm. The etch-stop layer protects the bottom cap layer 14 underneath from damage when etching the top cap layer 16.

The top cap layer 16 comprises III-nitride semiconductors. In one example, the top cap layer 16 comprises Mg-doped GaN or AlGaN with doping density between 1E17/cm³ and 1E21/cm³. In another example, the top cap layer comprises InGaN with an In composition less than 30%. The top cap layer 16 may be between 10 nm and 100 nm. The top cap layer 16 may have a lower aluminum composition than the etch stop layer 15.

Next, as shown in FIG. 2B, a mask 30 is disposed above the top cap layer 16 in the region that will ultimately be the gate region. As shown in Box 610 and FIG. 2C, the top cap layer 16 is etched outside the gate region. This etch process is highly selective to the top cap layer 16 over the etch stop layer 15. In some embodiments, this etch process may be performed using a plasma containing fluorine or oxygen in combination with chlorine. In another embodiment, a plasma containing boron trichloride and/or sulfur hexafluorine is used. This etch process removes the top cap layer 16 with little effect on the etch stop layer 15, as shown in FIG. 2C.

As shown in Box 620 and FIG. 2D, the etch stop layer 15 is removed using an etch process. This may be achieved using tetramethylammonium hydroxide (TMAH). Alternatively, a standard clean 1 (SC1), which includes a solution of ammonium hydroxide (NH₃OH), hydrogen peroxide (H₂O₂) and water, or other suitable wet chemistry etch methods may be used. These etch processes may be selective to the etch stop layer 15 over the bottom cap layer 14. Alternatively, digital etch methods may be used. In one embodiment, an oxygen plasma is used in conjunction with a wet HCl etch to remove the etch stop layer 15 such that the bottom cap layer 14 is minimally affected by this etch process.

The mask 30 is then removed, as shown in FIG. 2E. After the mask 30 is removed, a dielectric layer 17 is deposited over the entire structure, as shown in Box 630 and FIG. 2F. The dielectric layer 17 may be made of material selected from SiₓN_{y}, SiO₂, SiOₓN_{y}, Al₂O₃, and any other suitable dielectric and their combinations.

Next, as shown in Boxes 640-650 and FIG. 2G, the source electrode 18 and drain electrode 19 are created. The source electrode 18 and drain electrode 19 are made of material selected from Ti, Al, TiN, W, WN, Ni, Au, Mo, Si and any other suitable conductive material. The source electrode 18 and drain electrode 19 form ohmic contacts to the channel layer 12 underneath through a recess into the dielectric layer 17. In one example, the bottom of the source electrode 18 and drain electrode 19 are in contact with the barrier layer 13 through a recess in the dielectric layer 17 and the bottom cap layer 14. In other embodiments, the bottom of the source electrode 18 and drain electrode 19 are deposited on top of the bottom cap layer 14, in the barrier layer 13 or below the bottom of the barrier layer 13 in contact with the channel layer 12. In another example, heavily doped n+ GaN region is formed underneath the source and drain ohmic contacts through ion implantation or the ohmic regrowth process. In each of these embodiments, the source electrode 18 and the drain electrode 19 are disposed in ohmic contact regions to form an electrical connection to electrons at the interface between the channel layer 12 and the barrier layer 13.

Finally, as shown in Box 660 and FIG. 2H, the gate electrode 20 is formed by etching the dielectric layer 17 in the gate region and depositing the gate metal on top of the top cap layer 16. The gate metal may be selected from the materials such as Ti, TiN, Al, Ni, Tungsten, Cu or any other suitable metals and combination of the metals. The transistor shown in FIG. 2H may be either normally-on transistor with electrons in the channel layer 12 underneath the gate region connecting the source and drain when the gate electrode 20 is not biased, or normally-off transistor with the electrons absent from the channel layer 12 underneath the gate region when the gate electrode 20 is not biased.

There are variations of this fabrication sequence. For example, the order in which the gate electrode 20 and the source and drain electrodes are formed may be changed. Further, additional process steps, which are not shown here, include depositing additional dielectric layers, forming of field plates and interconnections.

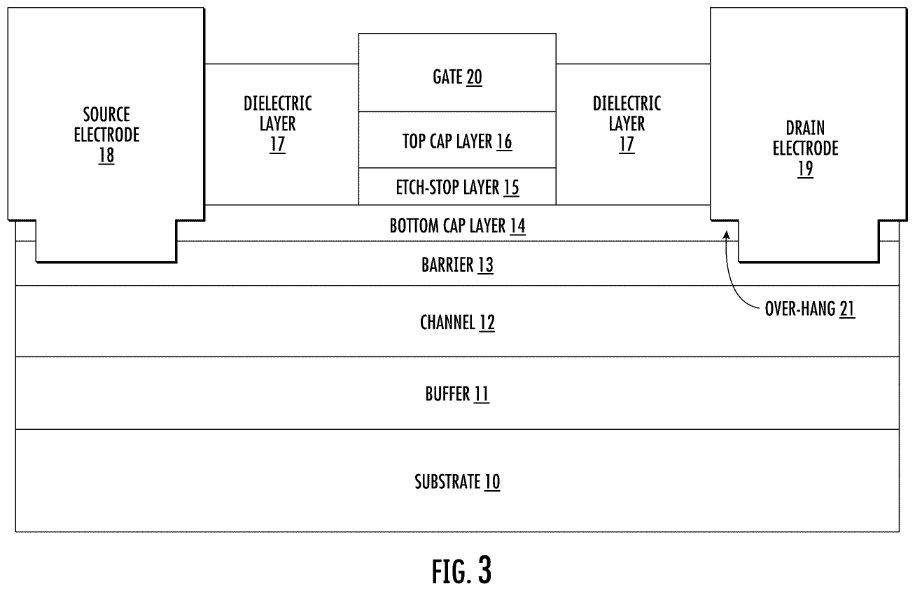

In another example, as shown in FIG. 3, the source electrode 18 and drain electrode 19 have an over-hang region 21 contacting the bottom cap layer 14 while the bottom of the source and drain electrodes contacts the barrier layer 13. It is also possible to have source and drain electrodes over-hang on top of the dielectric layer 17.

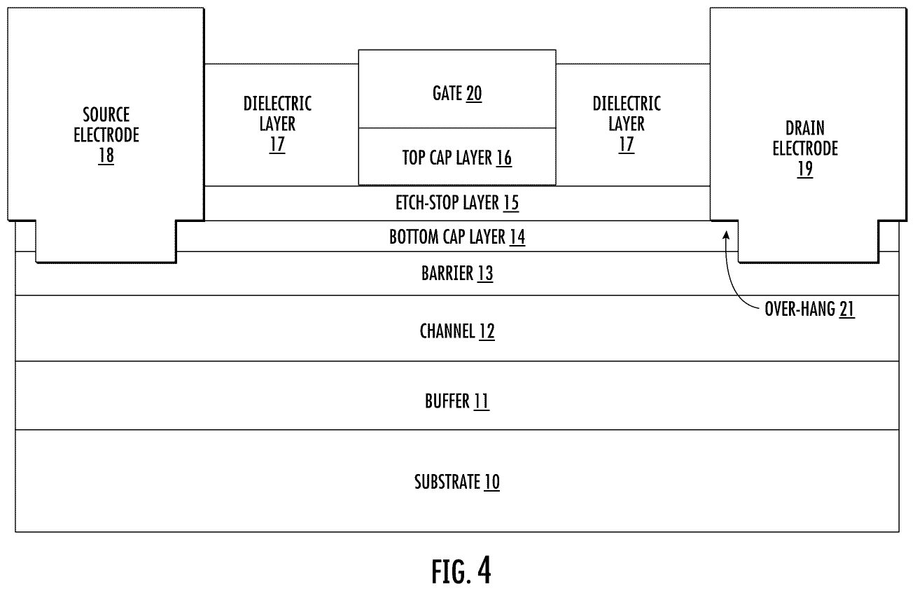

In yet another embodiment, the etch stop layer 15 may be present outside the gate region, as shown in FIG. 4. In this embodiment, the process shown in FIG. 2D may be omitted.

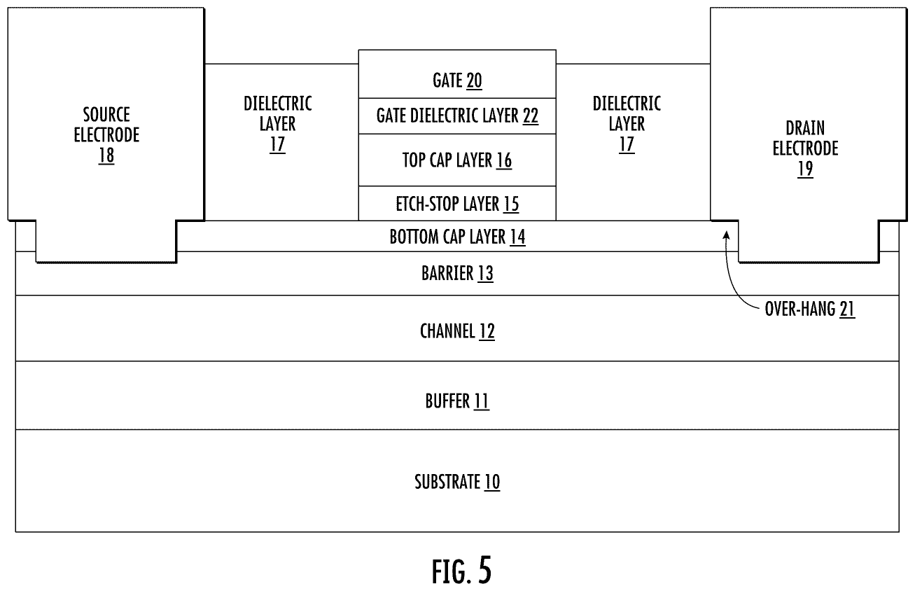

In yet another embodiment, a gate dielectric layer 22 may be disposed between the gate electrode 20 and the top cap layer 16, as shown in FIG. 5. The gate dielectric layer 22 may be as thin as 0.5 nm and may be made of dielectric materials such as SiₓN_{y}, SiO₂, SiₓO_{y}N_{z}, Al₂O₃, or any other suitable dielectric material or a combination thereof. The gate dielectric layer 22 may cover the side wall of the top cap layer 16. In some embodiments, the gate dielectric layer 22 may not cover the entire surface of the top cap layer 16. This gate dielectric layer 22 may be deposited after the top cap layer 16 (after FIG. 2A), or at a different point in the process, such as before the deposition of the gate electrode 20 (before FIG. 2H). Note that the gate dielectric layer 22 may be added to any of the embodiments described herein, including FIG. 2H, 3, or 4.

Thus, in all of these embodiments, the III-Nitride transistor has a top cap layer 16, an etch stop layer 15, and a bottom cap layer 14 disposed between the gate electrode 20 and the barrier layer 13. In certain embodiments, a gate dielectric layer 22 may also be disposed between the top cap layer 16 and the gate electrode 20.

Further, additional passivation dielectric and field plate structures may be applied to the transistors shown in FIGS. 2H, 3, 4 and 5.

The system described herein have many advantages. As described above, the traditional fabrication techniques result in a barrier layer that is exposed to plasma etching, which may result in etch related variations. By including an etch stop layer sandwiched by two cap layers, the barrier layer is no longer exposed to this harmful plasma. Therefore, the device to device variation caused by this etching process may be reduced.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A semiconductor structure for use in a III-Nitride (III-N) semiconductor device, comprising:
a channel layer;
a barrier layer, wherein electrons are formed at an interface between the channel layer and the barrier layer;
a source electrode and a drain electrode disposed in ohmic contact regions to form an electrical connection to electrons at the interface between the channel layer and the barrier layer;
a gate electrode disposed between the source electrode and the drain electrode in a gate region;
a bottom cap layer disposed on the barrier layer;
an etch stop layer disposed on the bottom cap layer; and
a top cap layer disposed beneath the gate electrode and on the etch stop layer.

2. The semiconductor structure of claim 1, wherein the bottom cap layer extends from the drain electrode to the source electrode.

3. The semiconductor structure of claim 1, wherein the top cap layer is disposed only in the gate region.

4. The semiconductor structure of claim 1, wherein the top cap layer comprises Mg-doped p-type GaN or InGaN or a III-Nitride semiconductor that has a lower Al composition than the etch stop layer.

5. The semiconductor structure of claim 1, wherein the etch stop layer is disposed only in the gate region.

6. The semiconductor structure of claim 1, wherein the etch stop layer extends from the drain electrode to the source electrode.

7. The semiconductor structure of claim 1, wherein the etch stop layer comprises a higher aluminum composition than the bottom cap layer.

8. The semiconductor structure of claim 7, wherein the etch stop layer comprises AlN.

9. The semiconductor structure of claim 1, wherein the bottom cap layer comprises a lower aluminum composition than the barrier layer.

10. The semiconductor structure of claim 9, wherein the bottom cap layer comprises GaN.

11. The semiconductor structure of claim 1, further comprising a gate dielectric layer disposed between the gate electrode and the top cap layer.

12. A method of fabricating a III-Nitride (III-N) semiconductor device, comprising:
depositing on a substrate, a buffer layer, a channel layer, a barrier layer, a bottom cap layer, an etch stop layer and a top cap layer, wherein the etch stop layer has a higher aluminum composition than the bottom cap layer and the top cap layer;
using a mask to remove a portion of the top cap layer, using an etch process that is highly selective to the top cap layer over the etch stop layer;
removing the mask;
depositing a dielectric layer over an entirety of the substrate;
depositing a source electrode and a drain electrode in ohmic contact regions to form an electrical connection to electrons at an interface between the channel layer and the barrier layer;
removing a portion of the dielectric layer in a gate region; and
depositing a gate electrode on top of the top cap layer in the gate region.

13. The method of claim 12, further comprising etching a portion of the etch stop layer after etching the top cap layer and before removing the mask.

14. The method of claim 13, wherein the etching the etch stop layer is performed using tetramethylammonium hydroxide (TMAH), a standard clean 1 (SC1), which includes a solution of ammonium hydroxide (NH₃OH), hydrogen peroxide (H₂O₂) and water, or an oxygen plasma in conjunction with a wet HCl etch.

15. The method of claim 12, wherein the etching of the top cap layer is performed using a plasma containing fluorine or oxygen in combination with chlorine, or a plasma containing boron trichloride and/or sulfur hexafluorine.

16. The method of claim 12, wherein the etch stop layer comprises AlN.

17. The method of claim 12, wherein the bottom cap layer comprises GaN.

18. The method of claim 12, wherein the top cap layer comprises Mg-doped p-type GaN or InGaN or a III-Nitride semiconductor that has a lower Al composition than the etch stop layer.
